(19) United States
(12) Patent Application Publication
(10) Pub. No.: US 2020/0035586 A1
(43) Pub. Date: Jan. 30, 2020

(54) CHIP-ON-LEAD SEMICONDUCTOR DEVICE PACKAGES WITH ELECTRICALLY ISOLATED SIGNAL LEADS

(71) Applicant: SEMICONDUCTOR COMPONENTS INDUSTRIES, LLC, Phoenix, AZ (US)

(72) Inventors: Jin Yoong LIONG, Seremban (MY); Soon Wei WANG, Seremban (MY); How Kiat LIEW, Bukit Jalil (MY)

(73) Assignee: SEMICONDUCTOR COMPONENTS INDUSTRIES, LLC, Phoenix, AZ (US)

(21) Appl. No.: 16/045,275

(22) Filed: Jul. 25, 2018

(51) Int. Cl. H01L 23/495; H01L 23/31; H01L 23/00

(52) U.S. Cl. CPC H01L 23/4951; H01L 23/49517; H01L 24/09; H01L 24/49; H01L 23/3114

(57) ABSTRACT

In a general aspect, a chip-on-lead semiconductor device package can include a leadframe having a plurality of signal leads. The plurality of signal leads can include at least two signal leads each having a first face with a first surface area and, opposite the first face, a second face with a second surface area, the second faces of the at least two signal leads being exposed on a surface of the chip-on-lead device package. The plurality of signal lead can also include at least one signal lead having a first face with a third surface area and, opposite the first face of the at least one signal lead, a second face with the second surface area, the second face of the at least one signal lead being exposed on the surface of the chip-on-lead semiconductor device package.

### TECHNICAL FIELD

This description relates to semiconductor device packages. More specifically, this description relates to chip-on-lead semiconductor device packages.

### BACKGROUND

Semiconductor devices (semiconductor die) can be implemented in various semiconductor device packaging assemblies (packaging assemblies). In some packaging assemblies, an isolated die attach paddle (DAP) can be included, and a semiconductor die can be coupled with the DAP in the packaging assembly (e.g., where the DAP is electrically isolated from signal leads of the packaging assembly). Such implementations allow for the semiconductor die to be electrically isolated from signal leads of the packaging assembly (e.g., in the absence of a separate electrical connection from the signal leads to the DAP), as a result of the electrical isolation of the DAP.

In some implementations, a semiconductor device packaging assembly may exclude a DAP, and a semiconductor die implemented in such packaging assemblies can be disposed, in part, on surfaces of the signal leads of the packaging assembly. Such assemblies can be referred to as chip-on-lead semiconductor package assemblies (COL assemblies). COL assemblies however, can have certain drawbacks. For example, electrical failures of the semiconductor die (e.g., when tested against performance specifications) can occur in such assemblies. For instance, excessive leakage (e.g., above a specified limit) can occur between the signal leads (e.g., high voltage signal leads) of a COL assembly and a corresponding semiconductor die that is included in the assembly, where the semiconductor die is coupled with (attached to, mounted on, affixed to, etc.) the signal leads of the assembly.

### SUMMARY

In a general aspect, a chip-on-lead (COL) semiconductor device package (package) can include a semiconductor die having a front side surface and a back side surface. The back side surface can be opposite the front side surface. The COL package can also include a leadframe having a plurality of signal leads. The plurality of signal leads can include at least two signal leads each having a first face with a first surface area and, opposite the first face, a second face with a second surface area, the second faces of the at least two signal leads being exposed on a surface of the chip-on-lead device package. The plurality of signal lead can also include at least one signal lead having a first face with a third surface area and, opposite the first face of the at least one signal lead, a second face with the second surface area, the second face of the at least one signal lead being exposed on the surface of the chip-on-lead semiconductor device package. The back side surface of the semiconductor die can be coupled with the first faces of the at least two signal leads. The first face of the at least one signal lead can be laterally disposed from the back side surface of the semiconductor die.

In another general aspect, a chip-on-lead (COL) semiconductor device package (package) can include a premolded leadframe including a plurality of signal leads and a molding compound. The plurality of signal leads can include at least two signal leads each having a first face with a first surface area and, opposite the first face, a second face with a second surface area, the first faces of the at least two signal leads being exposed on a first surface of the premolded leadframe, and the second faces of the at least two signal leads being exposed on a second surface of the premolded leadframe opposite the first surface of the premolded leadframe. The plurality of signal leads can also include at least one signal lead having a first face with a third surface area and, opposite the first face of the at least one signal lead, a second face with the second surface area, the first face of the at least one signal lead being exposed on the first surface of the premolded leadframe, and the second face of the at least one signal lead being exposed on the second surface of the premolded leadframe. The COL package can also include a semiconductor die having a front side surface and a back side surface. The back side surface can be opposite the front side surface. The back side surface of the semiconductor die can be coupled with the first faces of the at least two signal leads and the molding compound on the first surface of the premolded leadframe. The first face of the at least one signal lead can be laterally disposed from the back side surface of the semiconductor die.

In another general aspect, a chip-on-lead (COL) semiconductor device package (package) can include a semiconductor die having a front side surface and a back side surface. The back side surface being opposite the front side surface. The COL package can also include a leadframe having a plurality of signal lead. A first subset of the plurality of signal leads can be arranged along a first edge of the COL package. A second subset of the plurality of signal leads can be arranged along a second edge of the COL package. The second edge can be opposite the first edge. A first signal lead of the first subset of the plurality of signal leads can be spaced a first distance from a first signal lead of the second subset of the plurality of signal leads. The first signal lead of the second subset of the plurality of signal leads can be respectively arranged, in the COL package, directly opposite the first signal lead of the first subset of the plurality of signal leads. A second signal lead of the first subset of the plurality of signal leads can be spaced a second distance from a second signal lead of the second subset of the plurality of signal leads. The second signal lead of the second subset of the plurality of signal leads can be respectively arranged, in the chip-on-lead semiconductor device package, directly opposite the second signal lead of the first subset of the plurality of signal leads. The second distance can be greater than the first distance. The back side surface of the semiconductor die can be coupled with the first signal lead of the first subset of the plurality of signal leads, the first signal lead of the second subset of the plurality of signal leads and the second signal lead of the first subset the plurality of signal leads. The COL package can also include a molding compound that can be disposed between the back side surface of the semiconductor die and the second signal lead of the second subset of the plurality of signal leads.

### BRIEF DESCRIPTION OF THE DRAWINGS

FIG. 1A is a plan view of a leadframe for a chip-on-lead (COL) semiconductor device package from a first side.

FIG. 1B is a plan view of the leadframe of FIG. 1A from a second side, the second side being opposite the first side.

FIG. 2 is an isometric view of a premolded leadframe, such as including the leadframe of FIGS. 1A and 1B, for a COL semiconductor device package.

FIG. 3 is an isometric view of a COL semiconductor device package that includes the leadframe of FIGS. 1A and 1B, or the premolded leadframe of FIG. 2.

FIG. 4 is a cross-sectional diagram of the COL semiconductor device package of FIG. 3.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated.

### DETAILED DESCRIPTION

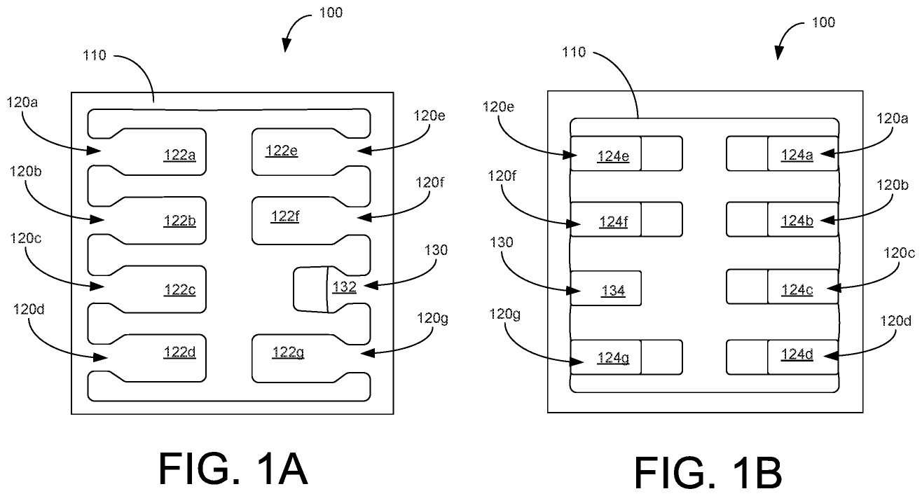

FIG. 1A is a plan view of a leadframe 100 for a chip-on-lead (COL) semiconductor device package (package) from a first side. FIG. 1B is a plan view of the leadframe 100 of FIG. 1A from a second side, the second side being opposite the first side. That is, as shown in FIG. 1B, the leadframe 100 is illustrated as being inverted from the view shown in FIG. 1A. For purposes of this disclosure, the view of the leadframe 100 shown in FIG. 1A will be referred to as a top side view, while the view of the leadframe 100 shown in FIG. 1B will be referred as a back side view.

As shown in FIGS. 1A and 1B, the leadframe 100 can include an outer frame 110 and signal leads 120a, 120b, 120c, 120d, 120e, 120f, 120g and 130. The outer frame 110, can be formed along with the signal leads 120a-120g and 130 as part of a leadframe production process for producing the leadframe 100. Such a production process can include a number of operations that are used to form the leadframe 100, such as from a metal (e.g., copper, aluminum, metal alloy, etc.) sheet. Such operations can include rolling, stamping, chemical etching, etc. The outer frame 110 can be configured to retain the signal leads 120a-120g and 130 in place during a semiconductor device assembly process, with the outer frame 110 being removed at an appropriate point in the assembly process, so as to separate (physically and electrically) the signal leads 120a-120g and 130 from one another (e.g., to separate the COL package from the outer frame 110). In some implementations, the leadframe 100 can be included in a strip or matrix of leadframes, from which a plurality of semiconductor device assemblies (COL packages) can be produced.

As illustrated in FIGS. 1A and 1B, the signal leads 120a-120g have a first configuration, while the signal lead 130 has a second configuration. As described herein, leadframe implementations, such as the leadframe 100, can overcome drawbacks of current COL package leadframes. For instance, in some implementations, the signal lead 130 (or other similarly configured signal leads) can prevent electrical (e.g., leakage) failures of a semiconductor die in corresponding COL packages (e.g., COL packages including a leadframe, such as the leadframe 100).

While the leadframe 100, as illustrated in FIGS. 1A and 1B, includes one signal lead having the configuration of signal lead 130, the arrangement of the leadframe 100 is given by way of example. In in some implementations, a leadframe for a COL package can include a plurality of signal leads having the configuration of the signal lead 130 (or a signal leads of a similar configuration). Further, in some implementations, a leadframe for a COL package can have other arrangements of signal leads having the configurations (or similar configurations) of the signal leads 120a-120 and 130. For instance, a number of signal leads of each configuration (e.g., the configuration of the signal leads 120a-120g, or the configuration of the signal lead 130) included in a leadframe for a given COL package, and organization of those signal leads in the corresponding COL package will depend on the particular implementation, such as on an arrangement of a corresponding semiconductor die being implemented in a COL package.

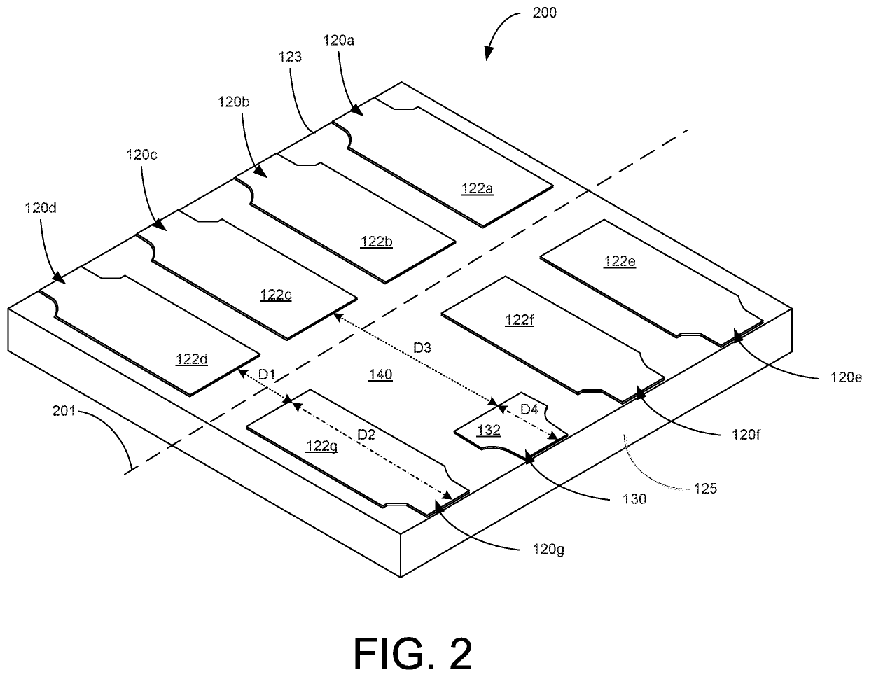

As shown in FIG. 1A, for the leadframe 100, the signal leads 120a-120g each have a first face on the top side of the leadframe 100, respectively faces 122a, 122b, 122c, 122d, 122e, 122f and 122g with a first surface area (e.g., as shown in FIG. 1A). In some implementations, in a correspond COL package, a semiconductor die can be mounted on the faces 122a-122g of the signal leads 120a-120g, such as in the implementation shown in FIG. 2.

As shown in FIG. 1B, opposite the first faces 122a-122g on the backside of the leadframe 100, the signal leads 120a-120g each have a second face, respectively faces 124a, 124b, 124c, 124d, 124e, 124f and 124g, with a second surface area. In some implementations, such as those described herein, the second faces 124a-124g of the signal leads 120a-120g can be exposed on a surface of a corresponding COL package, e.g., as electrical contacts to a semiconductor die included in the COL package. In some implementations, the second surface area (e.g., of faces 124a-124g) can be less than the first surface area (e.g., of faces 122a-122g).

As further shown in FIGS. 1A, for the leadframe 100, the signal lead 130 can have a first face 132 on the top side of the leadframe 100 with a third surface area. As shown in FIG. 1B, opposite the first face 132 on the backside of the leadframe 100, the signal lead 130 has a second face 134, with the second surface area (e.g., the surface area of the faces 124a-124g of the signal leads 120a-122g). In some implementations, such as those described herein, the second face 134 of the signal lead 130 can be exposed on a same surface of a COL package as the faces 124a-124g (e.g., as another electrical contacts to a semiconductor die included in the COL package, such for a high voltage signal of 50 V or greater). In some implementations, the third surface area (e.g., of the faces 134) can be less than the first surface area (e.g., of faces 122a-122g), and less than the second surface area (e.g., of the faces 124a-124g).

FIG. 2 is an isometric view of a premolded leadframe 200 that can be used to implement a COL semiconductor device package assembly (a COL package). As illustrated in FIG. 2, the premolded leadframe 200 can be formed to include the leadframe 100 of FIGS. 1A and 1B. Accordingly, in FIG. 2, like reference numbers from FIGS. 1A and 1B are used to reference elements of the leadframe 100 in the premolded leadframe 200.

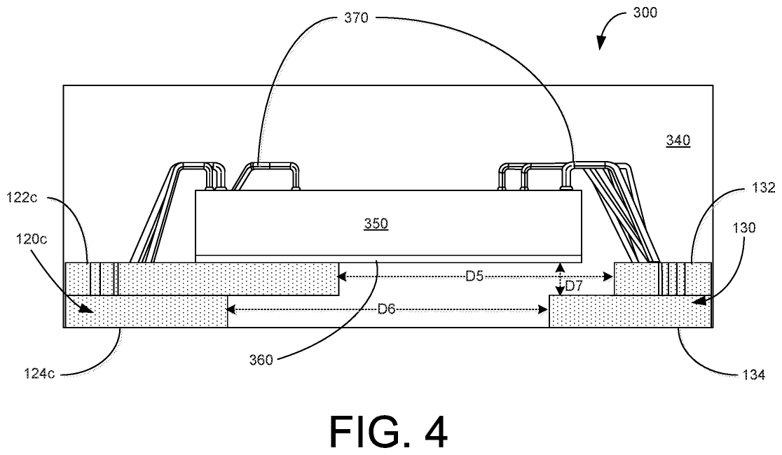

As illustrated in FIG. 2, in some implementations, the leadframe 100 can be partially encapsulated in a molding compound 240, such as an epoxy molding compound. As shown in FIG. 2, the faces 122a-122g and 132 of the signal leads 120a-120g can be exposed through (coplanar with, etc.) a first surface of the molding compound 240 (e.g., an upward facing surface in FIG. 2). While not specifically shown in FIG. 2, the faces 124a-124g and 134 of the signal leads 120a-120g and 130 can be similarly exposed through (coplanar with, etc.) a second surface of the molding compound 240 (e.g., a downward facing surface of the premolded leadframe 200, such as illustrated in FIG. 4 for signal leads 120c and 130).

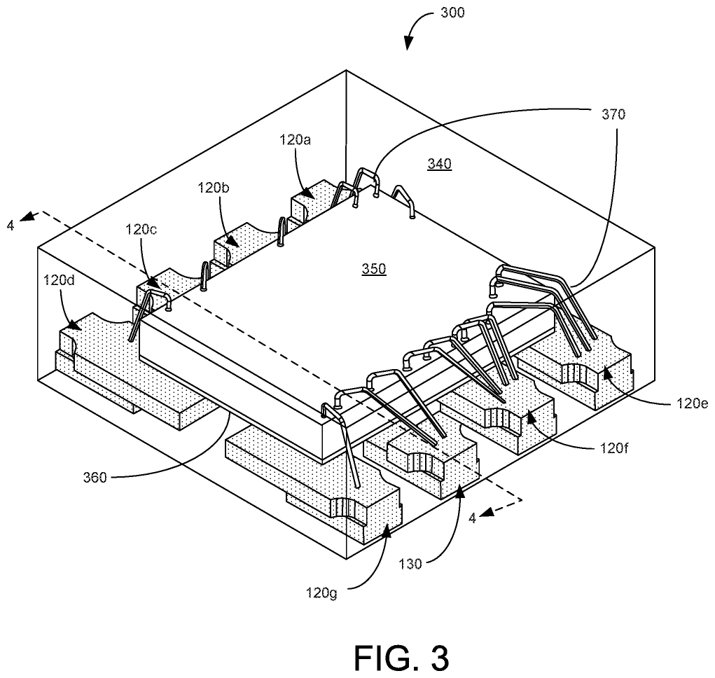

As noted above, the faces 124a-124g and 134 (exposed on the second surface of the premolded leadframe 200) can be used as electrical contacts to a semiconductor die included in a corresponding COL package (e.g., after wire bonding is used to electrically connect bond pads of the semiconductor die with the signal leads 120a-120g and 130, such as shown in FIG. 3). In some implementations, the molding compound 240 can be mechanically ground on the first surface and/or the second surface of the premolded leadframe 200 to expose the faces 122a-122g and 132 through the molding compound 240 on a first surface of the premolded leadframe 200 (e.g., the upward facing surface in FIG. 2), and/or to the expose the faces 124a-124g and 134 on a second surface of the premolded leadframe 200 (e.g., the downward facing, non-visible surface in FIG. 2).

As shown in FIG. 2, a first subset of the plurality of signal leads of the leadframe 100, including the signal leads 120a-120d, can be arranged along a first edge 123 of the premolded leadframe 200 (and a corresponding first edge a COL package including the premolded leadframe 200). As further shown in FIG. 2 a second subset of the plurality of signal leads, including the signal leads, 120e-120g and 130, can being arranged along a second edge 125 of the premolded leadframe 200 (and a corresponding second edge a COL package including the premolded leadframe 200). As shown in FIG. 2, the second edge 125 can be opposite the first edge 123.

As is shown in FIG. 2, depending on the particular configuration of the signal leads of the premolded leadframe 200 (e.g., the signal leads of the leadframe 100), respective spacings between signal leads that are arranged along the first edge 123 to respective signal leads that are opposite (directly opposite) along the second edge 125 can vary, as can respective distances from the signal leads to a center line 201 of the premolded leadframe 200. For instance, as can be seen in FIG. 2 the signal lead 120d (the face 122d of the signal lead 120d) is spaced a distance D1 from the signal lead 120g (the face 122g of the signal lead 120g) on the surface of the premolded leadframe 200 shown in FIG. 2, with each of the faces 122d and 122g of the signal leads 120d and 120g being a same distance from the center line 201, with the signal leads 120d and 120g being opposite each other (directly opposite each other) in the premolded leadframe 200. As also shown in FIG. 2, the signal lead 120c (the face 122c of the signal lead 120c) can be spaced a distance D2 from the signal lead 130 (the face 132 of the signal lead 130) on the surface of the premolded leadframe 200 shown in FIG. 2, where D2 is greater than D1, with the signal leads 120c and 130 being opposite each other (directly opposite each other) in the premolded leadframe 200. Further, the face 122c of the signal lead 120c, as shown in FIG. 2, is closer to the center line 201 than the face 132 of the signal lead 130.

FIG. 3 is an isometric view of a COL semiconductor device package 300 that includes the leadframe 100 of FIGS. 1A and 1B, or the premolded leadframe 200 of FIG. 2. The device 300, in FIG. 3, is illustrated as an X-ray view, where internal elements of the device 300 that would not be visible in a physical device implementation are, for purposes of illustration, shown in place in FIG. 3. As with FIG. 2, like reference numbers from FIGS. 1A and 1B are used to reference elements of the leadframe 100 (or the leadframe 100 of the premolded leadframe 200) in the device 300.

As shown in FIG. 3, the device 300 includes the signal leads 120a-120g and 130 of the leadframe 100 (or the premolded leadframe 200), a molding compound 340, a semiconductor die 350, a dielectric adhesive 360 and wire bonds 370. FIG. 3 also illustrates a section line 4-4, indicating a section line corresponding with the cross-sectional view of the device 300 shown in FIG. 4, which is discussed below.

In the device 300 of FIG. 3, the semiconductor die 350 can have a front side surface (e.g., upward facing) and a back side surface (e.g., downward facing), where the back side surface is opposite the front side surface. As shown in FIG. 3, the back side surface of the semiconductor die 350 can be coupled (e.g., via the dielectric adhesive 360) with the signal leads 120a-120d (e.g., with the faces 122a-122g of the signal leads 120a-120g). As also shown in FIG. 3, the signal lead 130 (e.g., the face 134 of the signal lead 103) can be laterally disposed from the back side surface of the semiconductor die 350. That is, the signal lead 130 (e.g., surfaces of the signal lead can be separated from the back side surface of the semiconductor die 350 by a portion of the molding compound 340. This separation can provide electrical isolation (in addition to the electrical isolation of the dielectric adhesive 360) between the signal lead 130 and the semiconductor die (e.g., the back side surface of the semiconductor die). Such additional electrical isolation can prevent electrical failures of the semiconductor die, such a prevent leakage between the signal lead 130 and the semiconductor die 350 when a high voltage (e.g., 50 V or greater) is applied to the signal pin 130.

As shown in FIG. 3, the dielectric adhesive 360 can be disposed between the semiconductor die 350 (e.g., a back side surface of the semiconductor die 350) and the signal leads 120a-120g of the leadframe 100 (or the premolded leadframe 200). In implementations of the device 300 that include a premolded leadframe (such as the premolded leadframe 200), the dielectric adhesive 360 can also be disposed between the semiconductor die 350 (e.g., a back side surface of the semiconductor die 350) and a molding compound (the molding compound 240) of the premolded leadframe 200.In some implementations, such as the device 300, the dielectric adhesive couples the semiconductor die 350 to the signal leads 120a-120g and 130 and/or to the molding compound 240 of the premolded leadframe 200. The dielectric adhesive can include, for example, a non-conductive epoxy, a non-conductive film and/or a non-conductive tape.

As shown in FIG. 3, the wire bonds 370 of the device 300 can be used to electrically couple the signal leads 120a-120g and 130 with the semiconductor die 350 (e.g., with respective bond pads disposed on the front side surface of the semiconductor die 350). In the device 300, the molding compound 340 can fully encapsulates the semiconductor die 350, the dielectric adhesive 360 and the wire bonds 370 (e.g., such that the semiconductor die 350, the dielectric adhesive 360 and the wire bonds 370 are encased (e.g., wholly encased) in the molding compound 340. Further, the molding compound 340 can at least partially encapsulate the leadframe. For example, the faces 124a-124g and 134 of the signal leads 120a-120g and 130 may be exposed through (e.g., not encapsulated in) the molding compound 340, to provide electrical contacts to the semiconductor die 350 external to the (COL package) device 300. In implementations the device 300 including a premolded leadframe, such as the premolded leadframe 200, the molding compound 340 can include a first molding compound (e.g., the molding compound 240 of the premolded leadframe 200), and also include a second molding compound that is used, in combination with the first molding compound, to encapsulate (fully encapsulate) the semiconductor die 350, the dielectric adhesive 360 and the wire bonds 370.

FIG. 4 is a cross-sectional diagram of the COL semiconductor device package (COL package) 300 of FIG. 3 corresponding with the section line 4-4 in FIG. 3. The device 300, as shown in FIG. 4, is illustrated as a partial X-ray view, where the wire bonds 370 of the device 300 that would not be visible in a physical device implementation (as they would be encased in the molding compound 340) are, for purposes of illustration, shown in place in FIG. 4. Also, as with FIGS. 2 and 3, like reference numbers from FIGS. 1A and 1B are used to reference elements of the leadframe 100 (or the leadframe 100 of the premolded leadframe 200) shown in the device 300, as illustrated in FIG. 4.

In the cross-sectional view of the device 300 shown in FIG. 4, the signal leads 120c and 130 of the device are shown. The distance D3 from FIG. 2 (e.g., the distance between the face 122c of the signal lead 120c and the face 132 of the signal lead 130) is also shown in FIG. 4. In some implementations, the signal lead 130 can be produced by performing an etch process during manufacturing of the leadframe 100. For instance, the signal lead 130 could, initially, be of substantially the same configuration as the other signal leads 120a-120g of the leadframe 100 (though mirrored as compared the signal lead 120c as shown in FIG. 4). A etch process (e.g., a half etch process, a partial etch process, etc.) could be performed to remove a portion of such a signal lead in order to produce the signal lead 130 from a signal lead having substantially the same configuration (construction, structure, etc.) as the signal leads 120a-120g of the leadframe 100.

As shown in FIG. 4, lower portions of the signal leads 120c and 130 (e.g., the portions that define, respectively, the faces 124c and 134) can be separated in the device 300 by spacing D5, which can be equal to D3, less than D3 or great than D3, depending on the particular implementation. As also shown in FIG. 4, the dielectric adhesive 360 (disposed on the back side surface of the semiconductor die 350) can be spaced from an internal surface of the lower portion of the lead 130 that defines the face 134 by a distance D6, where the distance D6 is filled with molding compound 340 to provide electrical isolation (in addition to the electrical isolation provided by the dielectric adhesive 340) between the signal lead 130 and the semiconductor die 350.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Silicon Carbide (SiC), Gallium Arsenide (GaAs), Gallium Nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A chip-on-lead semiconductor device package comprising:
a semiconductor die having a front side surface and a back side surface, the back side surface being opposite the front side surface; and
a leadframe having a plurality of signal leads, the plurality of signal leads including:
at least two signal leads each having a first face with a first surface area and, opposite the first face, a second face with a second surface area, the second faces of the at least two signal leads being exposed on a surface of the chip-on-lead device package; and
at least one signal lead having a first face with a third surface area and, opposite the first face of the at least one signal lead, a second face with the second surface area, the second face of the at least one signal lead being exposed on the surface of the chip-on-lead semiconductor device package,
the back side surface of the semiconductor die being coupled with the first faces of the at least two signal leads, the first face of the at least one signal lead being laterally disposed from the back side surface of the semiconductor die.

2. The chip-on-lead semiconductor device package of claim 1, further comprising a dielectric adhesive, the dielectric adhesive being disposed between the back side surface of the semiconductor die and the first faces of the at least two signal leads.

3. The chip-on-lead semiconductor device package of claim 2, wherein the dielectric adhesive couples the semiconductor die to the first faces of the at least two signal leads.

4. The chip-on-lead semiconductor device package of claim 2, wherein the dielectric adhesive includes at least one of a non-conductive epoxy, a non-conductive film or a non-conductive tape.

5. The chip-on-lead semiconductor device package of claim 1, further comprising a plurality of wire bonds electrically coupling the plurality of signal leads of the leadframe with respective bond pads disposed on the front side surface of the semiconductor die.

6. The chip-on-lead semiconductor device package of claim 5, further comprising a molding compound, wherein the molding compound:
fully encapsulates the semiconductor die and the wire bonds; and
at least partially encapsulates the leadframe,
a portion of the molding compound being disposed between the back side surface of the semiconductor die and the at least one signal lead, and
the second faces of the at least two signal leads and the second face of the at least one signal lead being exposed through the molding compound.

7. The chip-on-lead semiconductor device package of claim 1, wherein:
the second surface area is less than the first surface area; and
the third surface area is less than the first surface area.

8. The chip-on-lead semiconductor device package of claim 1, wherein the leadframe is a premolded leadframe, the back side surface of the semiconductor die being further coupled with a surface area of a molding compound of the premolded leadframe, the surface of the molding compound being coplanar with the first faces of the at least two signal leads and coplanar with the first face of the at least one signal lead.

9. A chip-on-lead semiconductor device package comprising:
a premolded leadframe including a plurality of signal leads and a molding compound, the plurality of signal leads including:
at least two signal leads each having a first face with a first surface area and, opposite the first face, a second face with a second surface area, the first faces of the at least two signal leads being exposed on a first surface of the premolded leadframe, and the second faces of the at least two signal leads being exposed on a second surface of the premolded leadframe opposite the first surface of the premolded leadframe; and
at least one signal lead having a first face with a third surface area and, opposite the first face of the at least one signal lead, a second face with the second surface area, the first face of the at least one signal lead being exposed on the first surface of the premolded leadframe, and the second face of the at least one signal lead being exposed on the second surface of the premolded leadframe; and
a semiconductor die having a front side surface and a back side surface, the back side surface being opposite the front side surface, the back side surface of the semiconductor die being coupled with the first faces of the at least two signal leads and the molding compound on the first surface of the premolded leadframe, the first face of the at least one signal lead being laterally disposed from the back side surface of the semiconductor die.

10. The chip-on-lead semiconductor device package of claim 9, further comprising a dielectric adhesive, the dielectric adhesive being disposed between the back side surface of the semiconductor die and the first surface of the premolded leadframe.

11. The chip-on-lead semiconductor device package of claim 10, wherein the dielectric adhesive couples the semiconductor die to the first surface of the premolded leadframe.

12. The chip-on-lead semiconductor device package of claim 10, wherein the dielectric adhesive includes at least one of a non-conductive epoxy, a non-conductive film or a non-conductive tape.

13. The chip-on-lead semiconductor device package of claim 9, wherein a portion of the molding compound is disposed between the back side surface of the semiconductor die and the at least one signal lead.

14. The chip-on-lead semiconductor device package of claim 9, further comprising a plurality of wire bonds electrically coupling the plurality of signal leads of the premolded leadframe with respective bond pads disposed on the front side surface of the semiconductor die.

15. The chip-on-lead semiconductor device package of claim 14, wherein the molding compound of the premolded leadframe is a first molding compound, the chip-on-lead semiconductor device package further comprising a second molding compound,
the second molding compound, in combination with the first molding compound, fully encapsulating the semiconductor die and the wire bonds.

16. The chip-on-lead semiconductor device package of claim 9, wherein:
the second surface area is less than the first surface area; and
the third surface area is less than the first surface area.

17. The chip-on-lead semiconductor device package of claim 9, wherein the third surface area is less than the first surface, and less than the second surface area.

18. A chip-on-lead semiconductor device package comprising:
a semiconductor die having a front side surface and a back side surface, the back side surface being opposite the front side surface; and
a leadframe having a plurality of signal leads, a first subset of the plurality of signal leads being arranged along a first edge of the chip-on-lead semiconductor device package, and a second subset of the plurality of signal leads being arranged along a second edge of the chip-on-lead semiconductor device package, the second edge being opposite the first edge,
a first signal lead of the first subset of the plurality of signal leads being spaced a first distance from a first signal lead of the second subset of the plurality of signal leads, the first signal lead of the second subset of the plurality of signal leads being respectively arranged, in the chip-on-lead semiconductor device package, directly opposite the first signal lead of the first subset of the plurality of signal leads,
a second signal lead of the first subset of the plurality of signal leads being spaced a second distance from a second signal lead of the second subset of the plurality of signal leads, the second signal lead of the second subset of the plurality of signal leads being respectively arranged, in the chip-on-lead semiconductor device package, directly opposite the second signal lead of the first subset of the plurality of signal leads, the second distance being greater than the first distance,
the back side surface of the semiconductor die being coupled with the first signal lead of the first subset of the plurality of signal leads, the first signal lead of the second subset of the plurality of signal leads and the second signal lead of the first subset the plurality of signal leads, and
a molding compound of the chip-on-lead semiconductor device package being disposed between the back side surface of the semiconductor die and the second signal lead of the second subset of the plurality of signal leads.

19. The chip-on-lead semiconductor device package of claim 18, further comprising a dielectric adhesive, the dielectric adhesive being disposed between the back side surface of the semiconductor die and the first signal lead of the first subset of the plurality of signal leads, the first signal lead of the second subset of the plurality of signal leads and the second signal lead of the first subset the plurality of signal leads.

20. The chip-on-lead semiconductor device package of claim 18, wherein the leadframe is a premolded leadframe, the back side surface of the semiconductor die being further coupled with a surface area of a molding compound of the premolded leadframe, the surface of the molding compound of the premolded leadframe being coplanar with respective surfaces of the plurality of signal leads, the molding compound of the premolded leadframe including the molding compound of the chip-on-lead semiconductor device package that is disposed between the back side surface of the semiconductor die and the second signal lead of the second subset of the plurality of signal leads.
